(19) United States
(12) Patent Application Publication
(10) Pub. No.: US 2026/0246432 A1
(43) Pub. Date: Aug. 20, 2026

(54) Analog Pre-Distorter

(71) Applicant: Altum RF International B.V., Eindhoven (NL)

(72) Inventor: Abdullah Celebi, Eindhoven (NL)

(21) Appl. No.: 19/542,416

(22) Filed: Feb. 17, 2026

(30) Foreign Application Priority Data
Feb. 18, 2025 (NL) 2039794

(51) Int. Cl. H03F 1/32; H03F 3/24

(52) U.S. Cl. CPC H03F 1/3241; H03F 3/245; H03F 2200/451

(57) ABSTRACT

Aspects of the present disclosure relate to an amplifier system, comprising an amplifier having an input terminal and an output terminal, and an analog pre-distorter, wherein the amplifier and at least part of the analog pre-distorter are integrated on a compound semiconductor die. According to the present disclosure, the analog pre-distorter comprises a parallel connection of a non-linear dissipative element and a reactive element, wherein one end of the parallel connection is connected to an input node and wherein another end of the parallel connection is connected to an output node. The pre-distorter further comprises a biasing unit for DC biasing the non-linear dissipative element. The non-linear dissipative element has a non-linear current-voltage relationship, wherein a dynamic resistance Rdyn of the non-linear dissipative element is such that for a given DC bias, a power gain of the analog pre-distorter expands when power of the RF signal is increased.

### BACKGROUND

Aspects of the present disclosure relate to an amplifier system comprising an amplifier and an analog pre-distorter.

In telecommunications systems, a power amplifier is typically used to amplify RF signals that are subsequently emitted using an antenna. When operating under large-signal conditions, power amplifiers generally display non-linear characteristics. These non-linear characteristics may result in unreliable or erroneous communication.

To avoid errors during communication, pre-distorting techniques may be used. These techniques comprise modifying the signal before it is amplified by the non-linear power amplifier. These modifications are most often conducted in the digital domain. For example, a look-up table can be used for transforming a digital non-pre-distorted base- band signal into a digital pre-distorted base-band signal. When the RF signal related to the digital pre-distorted base-band signal is amplified, the non-linear characteristics of the power amplifier can be corrected for, at least to a large extent. Unfortunately, implementing digital pre-distortion techniques can be relatively complex and costly.

Analog pre-distorting techniques are also known in the art. An example of an amplifier system 1000 comprising an analog pre-distorter 1 and a power amplifier PA1 is shown in FIG. 1. Here, pre-distorter 1 receives an RF signal at input RFin and outputs a pre-distorted RF signal to power amplifier PA1.

Pre-distorter 1 comprises a voltage source Vdd for biasing a diode D1 that is arranged in between power amplifier PA1 and input RFin. Capacitors C1 and C2 prevent DC signals from reaching power amplifier PA1 and input RFin, respectively. Resistor R1 and inductors L1, L2 provide a current path through diode D1 from voltage source Vdd to ground. Capacitor C3 provides an RF ground near voltage source Vdd.

Diode D1 is biased below its turn-on voltage such that under small-signal operation, diode D1 remains off, i.e. has a high impedance, during the entire cycle of the RF signal. In this case, only a small amount of RF signal passes through the diode due to its off-state capacitance. When the power of the RF signal is increased, diode D1 starts to operate above its turn on voltage during part of the cycle of the RF signal. Consequently, the effective impedance of diode D1 at the fundamental frequency of the RF signal is lower than during small-signal operation. Put differently, pre-distorter 1 displays a decrease in attenuation, or an increase in gain, as a function of the power of the RF signal. The power level at which such decrease starts depends on the DC bias setting of diode D1.

FIG. 2, top left, illustrates the real (R) and imaginary (I) parts of the impedance of diode D1 in Ohm (Q) at the fundamental frequency as function of the power of the RF signal in dB, whereas FIG. 2, top right, illustrates the corresponding magnitude (lZI) of the impedance. FIG. 2, bottom left and bottom right, illustrate the gain (G) in dB and phase shift (<D) in degrees of pre-distorter 1, respectively, as function of the power of the RF signal in dB. The phase shift corresponds to the phase shift between a signal emerging at the output, i.e. after capacitor C1, and a signal at the input RFin. As shown, pre-distorter 1 can be used for compensating gain compression and/or a phase shift increase of power amplifier PA1.

Pre-distorter 1 has several disadvantages. Firstly, although a relatively large variation in gain can be obtained, the absolute gain values are relatively low, e.g. << 0 dB. Secondly, some power amplifiers display a phase shift decrease instead of an increase as a function of power of the RF signal. The phase shift of these amplifiers cannot be corrected using pre-distorter 1.

### SUMMARY

An object of the present disclosures is to provide a pre-distorter in which these problems do not occur or at least to a lesser extent.

A pre-distorter according to a first aspect of the present disclosure comprises an input node for receiving an RF signal at an operational frequency ω, and an output node configured to be connected to an amplifier. The pre-distorter further comprises a parallel connection of a non-linear dissipative element and a reactive element, wherein one end of the parallel connection is connected to the input node and wherein another end of the parallel connection is connected to the output node. The pre-distorter also comprises a biasing unit for DC biasing the non-linear dissipative element.

The connection between the various ends of the parallel connection and the input node or output node can be direct, i.e. without further electrical components in between an end and a respective node, or indirect, i.e. with further electrical components in between an end and a respective node.

The non-linear dissipative element has a non-linear current-voltage relationship. A dynamic resistance R_{dyn} of the non-linear dissipative element decreases with increasing DC current through the non-linear dissipative element such that for a given DC current through the non-linear dissipative element, a power gain of the analog pre-distorter expands when power of the RF signal is increased.

Within the context of the present disclosure, the dynamic resistance is defined as the ratio between a small variation in the voltage across the non-linear dissipative element and the corresponding variation in current through the non-linear dissipative element. The dynamic resistance therefore corresponds and/or is related to the derivative of the current- voltage relationship of the non-linear dissipative element.

According to the first aspect of the present disclosure, when the power of the RF signal is increased, more power is routed through the reactive element and less power is routed through the non-linear dissipative element. Consequently, the gain of the pre- distorter expands when power of the RF signal is increased.

The non-linear element can be configured such that a ratio between a voltage swing of a voltage over the non-linear dissipative element and a current swing of a current through the non-linear dissipative element for said given DC bias current through the non- linear dissipative element increases when said voltage swing increases. More in particular, the DC current through the non-linear dissipative element is kept at least substantially constant when power is increased. When power is increased, the voltage and current swing will both increase. Because the average current over a cycle of the RF signal corresponds to the set DC bias current, and because the dynamic resistance increases with power, an increase in current swing will correspond to a proportionally larger voltage swing, thereby increasing the ratio between voltage swing and current swing. This translates into an increase in impedance at the operational frequency causing a larger part of the RF signal to be routed through the reactive element. As less of the RF signal is dissipated in the non- linear dissipative element, the overall gain of the pre-distorter will increase.

A pre-distorter according to a second aspect of the present disclosure comprises an input node for receiving an RF signal at an operational frequency ω, and an output node configured to be connected to an amplifier. The pre-distorter further comprises a parallel connection of a non-linear dissipative element and a reactive element, wherein one end of the parallel connection is connected to the input node and wherein another end of the parallel connection is connected to the output node. The pre-distorter also comprises a biasing unit for DC biasing the non-linear dissipative element.

The non-linear dissipative element has a non-linear current-voltage relationship, wherein a dynamic resistance R_{dyn} of the non-linear dissipative element increases with increasing DC bias voltage across the non-linear dissipative element such that for a given DC bias voltage across the non-linear dissipative element, a power gain of the analog pre- distorter expands when power of the RF signal is increased.

Similar to the first aspect of the present disclosure, according to the second aspect of the present disclosure, when the power of the RF signal is increased, more power is routed through the reactive element and less power is routed through the non-linear dissipative element. Consequently, the gain of the pre-distorter expands when power of the RF signal is increased.

The non-linear dissipative element can be configured such that a ratio between a voltage swing of a voltage over the non-linear dissipative element and a current swing of a current through the non-linear dissipative element for said given DC bias voltage over the non-linear dissipative element increases when said voltage swing increases. More in particular, the DC bias voltage over the non-linear dissipative element is kept at least substantially constant when power is increased. When power is increased, the voltage and current swing will both increase. Because the average voltage over a cycle of the RF signal corresponds to the set DC bias voltage, and because the dynamic resistance increases with power, an increase in voltage swing will correspond to a proportionally smaller current swing, This translates into an increase in impedance at the operational frequency causing a larger part of the RF signal to be routed through the reactive element. As less of the RF signal is dissipated in the non-linear dissipative element, the overall gain of the pre-distorter will increase.

The non-linear current-voltage relationship may describe a relationship between a value of the current through the non-linear dissipative element at a given time instant and a value of the voltage over the non-linear dissipative element at said given time instant. Preferably, a DC current-voltage relationship of the non-linear dissipative element at least substantially equals said non-linear current-voltage relationship.

The biasing unit can be configured to control the biasing of the non-linear dissipative element such that the dynamic resistance R_{dyn} of the non-linear dissipative element relates to a magnitude of the impedance Z of the reactive element at the operational frequency according to:

0.05R_{dyn} < IZI < 5R_{dyn}

With the impedance Z of the reactive element designed in this range, the desired impact on the gain of the pre-distorter when the power of the RF signal is increased can obtained.

The impedance Z of the reactive element at the operational frequency can be configured such that a phase delay imparted to the RF signal by the analog pre-distorter increases when power of the RF signal is increased. This behavior can for example be obtained when the reactive element comprises a capacitor.

Alternatively, the impedance Z of the reactive element at the operational frequency can be configured such that a phase delay imparted to the RF signal by the analog pre- distorter decreases when power of the RF signal is increased. This behavior can for example be obtained when the reactive element comprises an inductor. To prevent a DC current path through the reactive element, the parallel connection may comprise a DC block capacitor arranged in series with the reactive element. The impedance of the DC block capacitor at the operational frequency is much smaller than that of the inductor.

The non-linear dissipative element may comprise a diode. In this case, the biasing unit is configured to bias the diode above turn-on.

The analog pre-distorter may further comprise a buffer amplifier having a buffer input connected to said another end of the parallel connection, and a buffer output connected to the output node. By using a buffer amplifier, the impedance presented to the parallel connection can be controlled, thereby affecting the base level of the gain of the pre-distorter, i.e. the gain at low power levels of the RF signal, and the gain variation over the power range of the RF signal. The buffer amplifier may comprise a source follower or emitter follower.

In an embodiment, the non-linear dissipative element is arranged on a first semiconductor die and the source follower or emitter follower is arranged on a second semiconductor die different from the first semiconductor die. The semiconductor dies can be arranged in the same electronic package.

Alternatively, the non-linear dissipative element and the source follower or emitter follower are arranged on a same semiconductor die. This semiconductor die can be arranged in an electronic package.

According to a third aspect, the present disclosure provides an amplifier system that comprises an amplifier having an input terminal and an output terminal, wherein the amplifier is configured to amplify an RF signal received at its input terminal and wherein the amplifier displays gain compression and a phase shift between the input terminal and output terminal that decreases or increases with increasing power of the RF signal. The amplifier system further comprises the analog pre-distorter as described above of which the output node is connected to the input terminal of the amplifier. The analog pre-distorter is configured for at least partially compensating the gain compression and/or the increase or decrease of the phase shift.

The amplifier and the analog pre-distorter can be arranged on different semiconductor dies that may be packaged in separate packages. Alternatively, the amplifier and the analog pre-distorter are arranged on a same semiconductor die.

According to a fourth aspect of the present disclosure, a semiconductor die assembly is provided that comprises one or more semiconductor dies on which an analog pre-distorter is integrated. The analog pre-distorter comprises an input terminal for receiving an RF signal at an operational frequency ω, and an output terminal configured to be connected to an amplifier. The pre-distorter further comprises a parallel connection of a non-linear dissipative element and a reactive element, wherein one end of the parallel connection is connected to the input terminal and wherein another end of the parallel connection is connected to the output terminal. The pre-distorter additionally comprises a biasing terminal for receiving a DC bias current for DC biasing the non-linear dissipative element.

The non-linear dissipative element has a non-linear current-voltage relationship, wherein a dynamic resistance R_{dyn} of the non-linear dissipative element decreases with increasing DC current through the non-linear dissipative element such that for a given DC bias current through the non-linear dissipative element, a power gain of the analog pre- distorter expands when power of the RF signal is increased.

According to a fifth aspect of the present disclosure, a semiconductor die assembly is provided that comprises one or more semiconductor dies on which an analog pre- distorter is integrated. The analog pre-distorter comprises an input terminal for receiving an RF signal at an operational frequency ω, and an output terminal configured to be connected to an amplifier. The pre-distorter further comprises a parallel connection of a non-linear dissipative element and a reactive element, wherein one end of the parallel connection is connected to the input terminal and wherein another end of the parallel connection is connected to the output terminal. The pre-distorter additionally comprises a biasing terminal for receiving a DC bias voltage for DC biasing the non-linear dissipative element.

The non-linear dissipative element has a non-linear current-voltage relationship, wherein a dynamic resistance R_{dyn} of the non-linear dissipative element increases with increasing DC bias voltage across the non-linear dissipative element such that for a given DC bias voltage across the non-linear dissipative element, a power gain of the analog pre- distorter expands when power of the RF signal is increased.

The abovementioned examples of die assemblies may each be based on one or more semiconductor technologies among GaN field-effect transistor technology, Si laterally diffused metal oxide semiconductor technologies, InP or InGaP heterojunction bipolar transistor technology, GaAs field-effect transistor technology, and SiGe heterojunction bipolar transistor technology.

In the abovementioned semiconductor die assemblies, the amplifier can be integrated on one semiconductor die among the one or more semiconductor dies.

### BRIEF DESCRIPTION OF THE DRAWINGS

Next, aspects of the present disclosure are described in more detail referring to the appended drawings, wherein identical reference signs are used to refer to the same or similar components, and wherein:

FIG. 1 illustrates an amplifier system comprising a known analog pre-distorter;

FIG. 2 illustrates the characteristics of the pre-distorter of FIG. 1;

FIG. 3 illustrates an embodiment of an amplifier system in accordance with an aspect of the present invention;

FIG. 4 illustrates the characteristics of the pre-distorter of the amplifier system of FIG. 3;

FIG. 5A illustrates the I-V characteristics of the non-linear dissipative element of the pre-distorter of FIG. 3, and FIG. 5B illustrates the impact of the impedance with which the pre-distorter is loaded on the ability to correct for gain compression;

FIG. 6 illustrates a further embodiment of an amplifier system in accordance with an aspect of the present invention;

FIG. 7 illustrates characteristics of the pre-distorter of the amplifier system of FIG. 6;

FIG. 8 illustrates further characteristics of the amplifier system of FIG. 6;

FIG. 9 illustrates a further embodiment of an amplifier system in accordance with an aspect of the present invention;

FIG. 10 illustrates characteristics of the pre-distorter of the amplifier system of FIG. 9; and

FIG. 11 illustrates a pre-distorter in accordance with the present disclosure.

### DETAILED DESCRIPTION

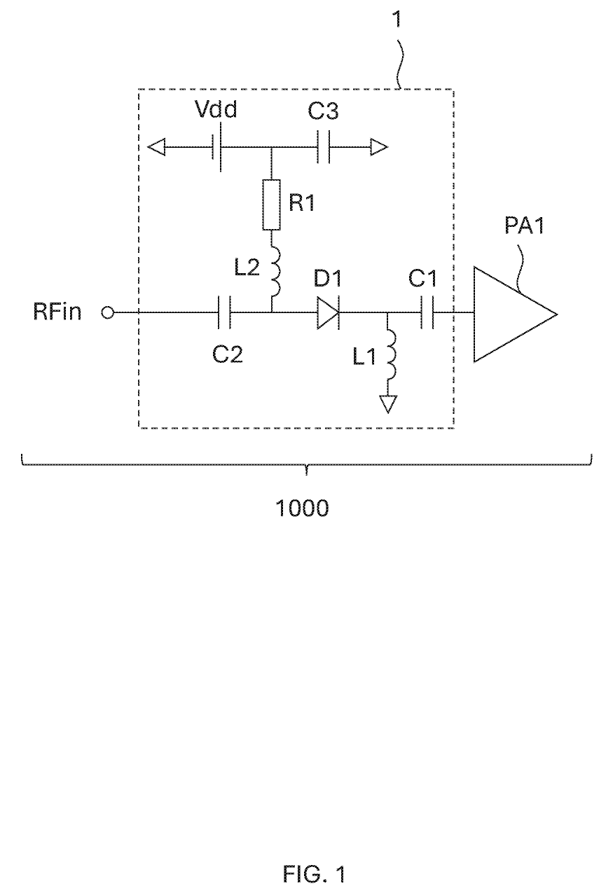

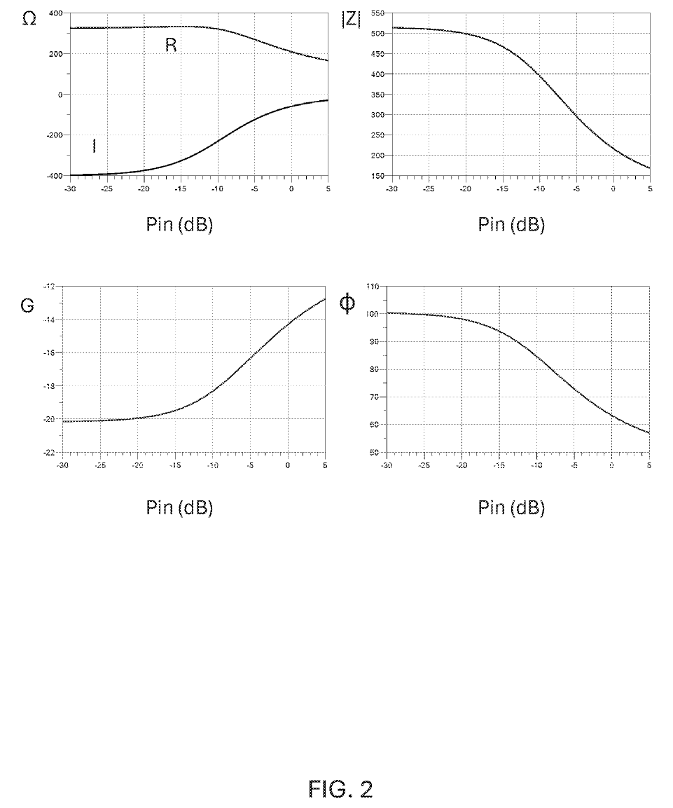

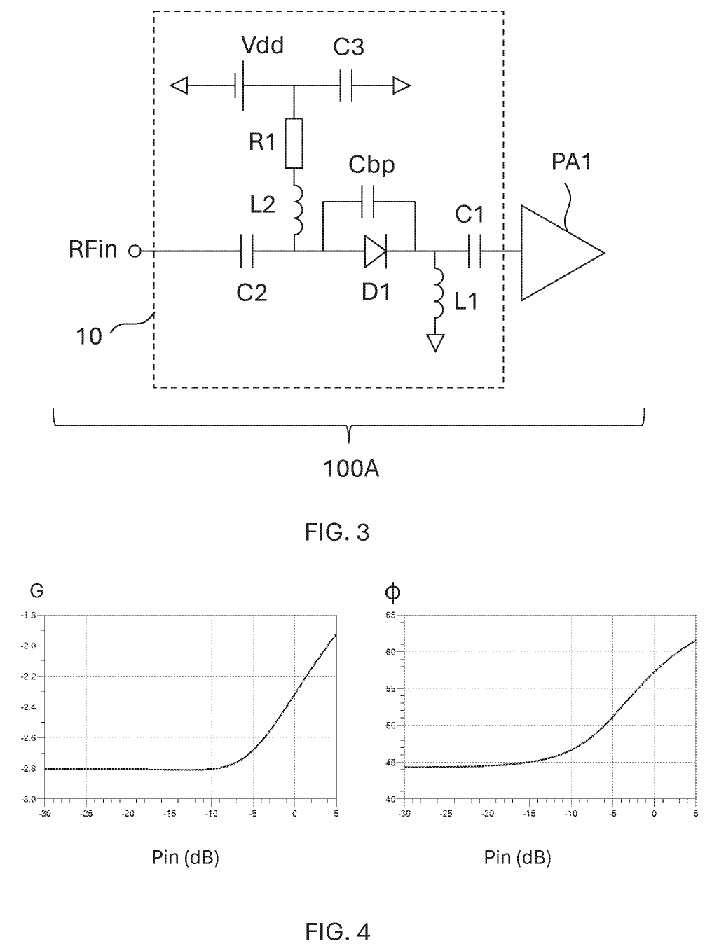

FIG. 3 illustrates an embodiment of an amplifier system 100A comprising a power amplifier PA1 and a pre-distorter 10 in accordance with the first aspect of the present disclosure. Compared to known pre-distorter 1 shown in FIG. 1, pre-distorter 10 comprises a reactive element in the form of a capacitor Cbp arranged in parallel to diode D1. Furthermore, diode D1 is biased by voltage source Vdd above its turn-on voltage.

FIG. 4 illustrates simulated characteristics of pre-distorter 10. Here, the characteristics are simulated using a 50 Ohm port connected to input RFin and a 50 Ohm port connected to capacitor C1. As shown, the base level of the gain (G), i.e. -2.8 dB, is much higher than that of pre-distorter 1 shown in FIG. 1. Furthermore, pre-distorter 10 displays an increase in phase shift (<) when the power of the input signal is increased, whereas pre-distorter 1 displays a decrease in phase shift. As most RF power amplifiers display gain compression and a phase shift decrease, pre-distorter 10 is more capable of compensating non-linear behavior of RF power amplifiers than pre-distorter 1.

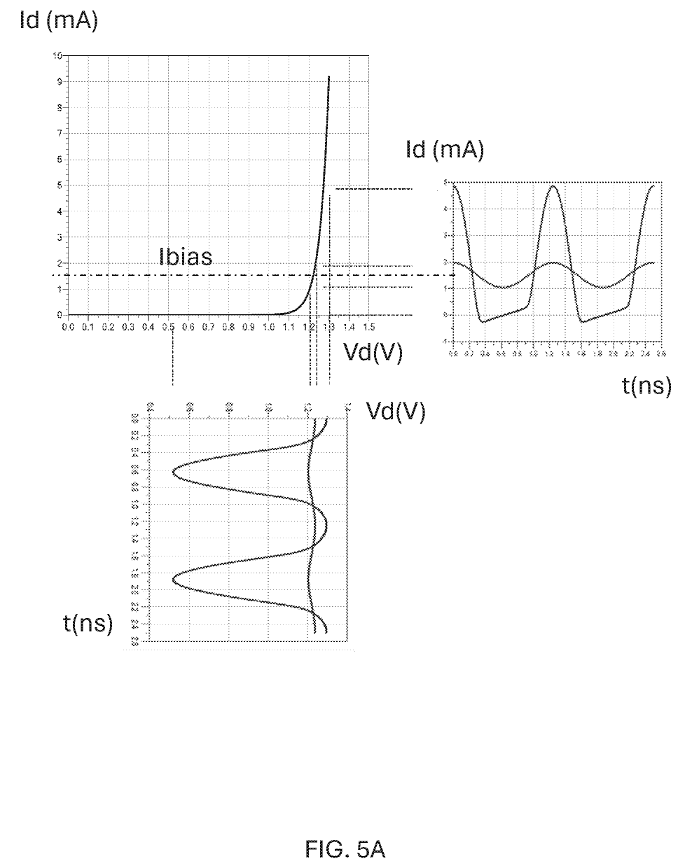

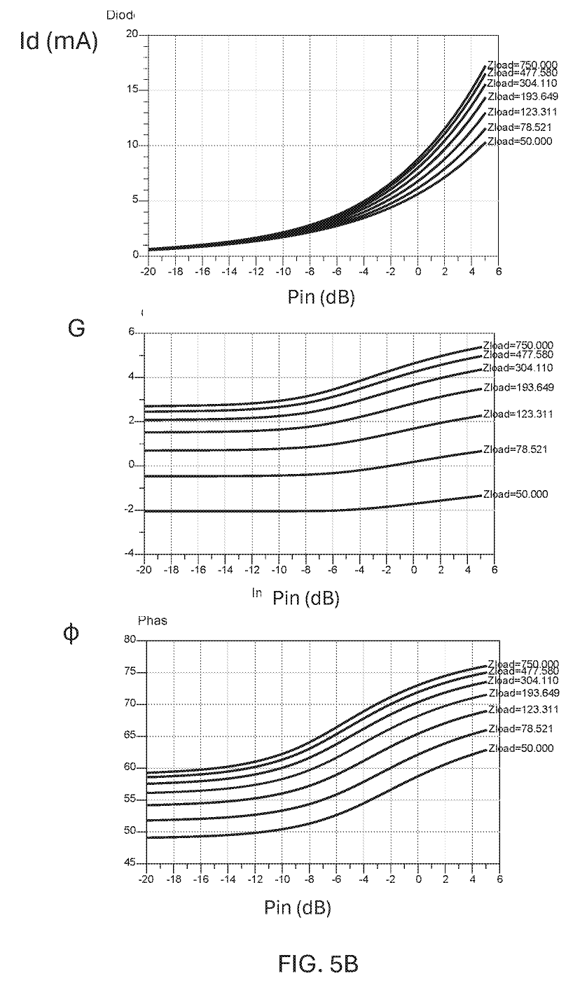

Next, the operational principles of pre-distorter 10 will be explained referring to FIG. 5A. In this figure, the non-linear current-voltage characteristics of diode D1 are shown in the upper left corner. These characteristics show the correlation between the momentary value of the voltage Vd across diode D1, e.g. the value at a given time instant (t) during an RF cycle, and the momentary value of the current Id through diode D1. Typically, these characteristics are substantially identical to the correlation between a DC value of the voltage across diode D1 and a DC value of the current through diode D1.

However, the present disclosure is not limited thereto. Other non-linear elements could be used that display different current-voltage characteristics at RF than at DC.

As shown in FIG. 5A, the current through diode D1 is biased at level Ibias substantially independent of the power of the RF signal. FIG. 5A illustrates the voltage and current swing when an RF signal is applied having a low power and a high power.

FIG. 5A, top right, shows that the current as a function of time varies around bias level Ibias, which equals 1.5 mA. The current waveform at low power is sinusoidal, whereas at high power, the waveform is distorted. Still, in both cases, the average current level equals Ibias.

FIG. 5A, bottom, shows the voltage as a function of time. Here, the DC volage differs between the low power and high power RF signals. More specifically, the DC voltage across diode D1 adjusts itself such that the average current through D1 equals Ibias.

Because the derivative of the curve in FIG. 5A top left increases with increasing voltage, the dynamic resistance decreases with increasing voltage. Due to this decrease, the amount of time that the momentary current is above Ibias is smaller than the amount of time that the momentary current is below Ibias. This is obtained by a voltage swing that has increased disproportionally compared to the current swing, and that has a lower average value. Accordingly, the ratio between the voltage swing and current swing has increased compared to the low power signal.

FIG. 5B illustrates the current Id at the fundamental frequency through the diode for different levels of power Pin of the input RF signal when the analog pre-distorter of FIG. 3 is not connected to an amplifier, such as amplifier PA1 in FIG. 3, but to a load having a real impedance Zload. As shown, this current shows a larger variation for larger load impedances. The Applicant therefore concluded that the ability of the pre-distorter to compensate gain compression can be changed by altering the load impedance that is presented to the pre-distorter. More specifically, the range over which gain compression can be compensated increases when the load impedance increases. This is shown in more detail in FIG. 5B, center and bottom figures, that show gain (G) and phase shift (ϕ).

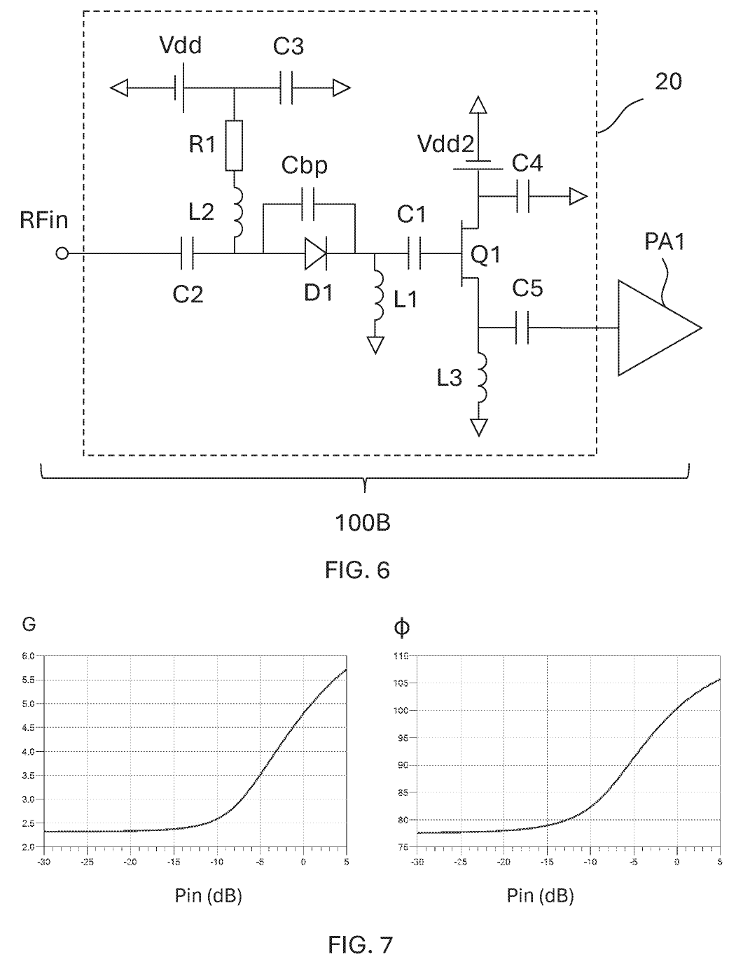

Based on this insight, a buffer amplifier having a high input impedance was utilized to obtain the abovementioned effect. This is shown for amplifier system 100B illustrated in FIG. 6. Compared to pre-distorter 10 of amplifier system 100A shown in FIG. 3, a buffer amplifier is inserted between capacitor C1 and power amplifier PA1. Here, the buffer amplifier corresponds to a source follower comprising a field-effect transistor Q1 that is biased using voltage source Vdd2 and inductor L3. Capacitor C4 provides an RF short near voltage source Vdd2 and capacitor C5 blocks DC signals from reaching power amplifier PA1.

Comparing the simulations of pre-distorter 20 in FIG. 7 to those of pre-distorter 10 in FIG. 4, again using 50 Ohm ports, it can be observed that the gain base level and gain variation have both increased. Similarly, a larger variation can be observed for the phase shift.

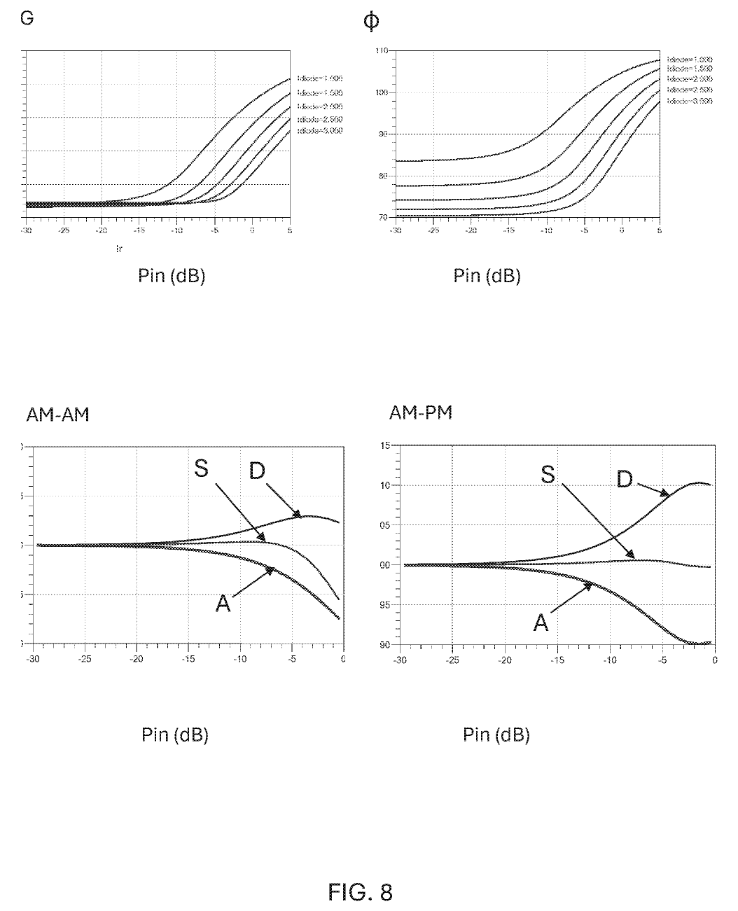

FIG. 8 illustrates simulations of amplifier system 100B of FIG. 6. Shown on the top left and right, are the gain and phase shift of pre-distorter 20, respectively, for different values of the DC bias current through diode D1. On the bottom left, the rate of change of gain with respect to the input power, AM-to-AM is depicted in dB/dB, and on the bottom right, the rate of change of phase with respect to the input power, AM-to-PM is depicted in degree/dB. The curves marked "A" are the AM-PM and AM-AM curves of only amplifier PA1. The curves marked "D" are the AM-PM and AM-AM curves of only pre-distorter 20. The curves marked "S" correspond to amplifier PA1 combined with pre-distorter 20, which are a superposition of the "A" and "D" curves. As can be observed, the combined AM-PM and AM-AM curves marked "S" are flatter with respect to the power of the RF signal compared to the AM-PM and AM-AM curves of just amplifier PA1 marked "A".

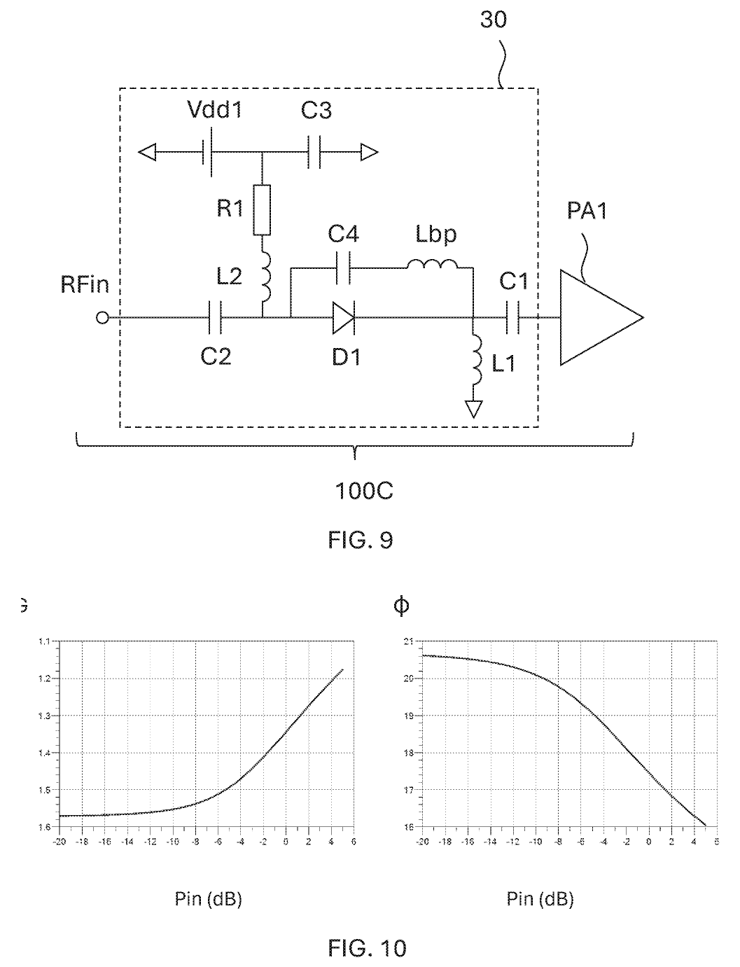

FIG. 9 illustrates a further embodiment of an amplifier system 100C comprising a power amplifier PA1 and a pre-distorter 30. Compared to pre-distorter 10, capacitor Cbp is replaced by a series connection of an inductor Lbp and capacitor C4. Here, capacitor C4 acts as a DC block. Its impedance at the operational frequency is negligible to that of inductor Lbp.

Simulations of pre-distorter 30 are shown in FIG. 10, again using 50 Ohm ports. Comparing FIG. 10 to FIG. 4, it can be observed that instead of a phase shift increase, a phase delay decrease can be observed. Hence, by changing between a capacitor and inductor as reactive element, different behavior of the power amplifier can be accounted for. Furthermore, amplifier system 100C may equally use a buffer amplifier as shown in FIG. 6.

To devise a general-purpose pre-distorter, both a capacitor and inductor can be used in the pre-distorter. Using switches or the like, either the capacitor or inductor can be selected for phase delay compensation.

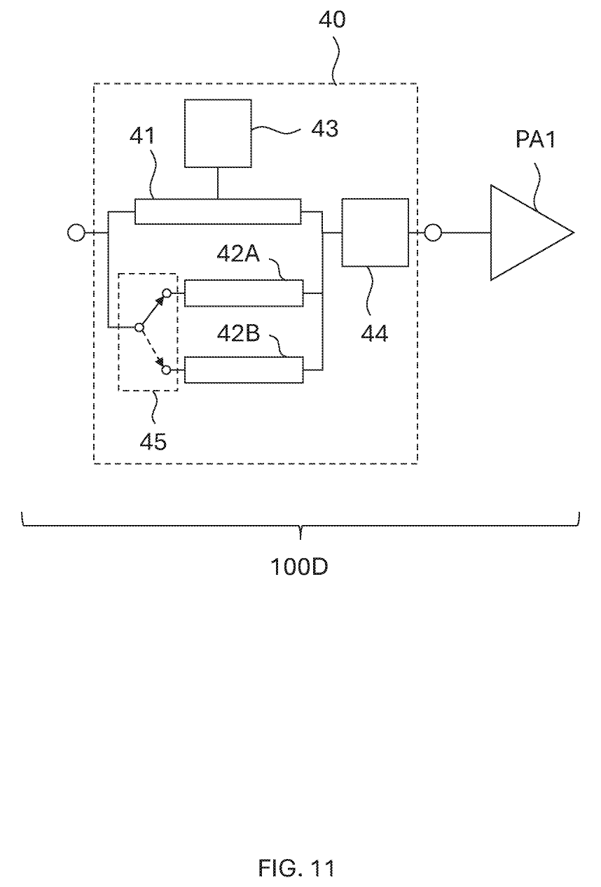

FIG. 11 illustrates a general amplifier system 100D comprising a power amplifier PA1 and a pre-distorter 40 in accordance with their present disclosure. Pre-disorter 40 comprises a parallel connection of a non-linear dissipative element 41 that biasing unit 43, and reactive elements 42A, 42B. For example, reactive element 42A could is biased using correspond to a capacitor as shown in 3 and reactive element 42B could correspond to an inductor in series with a capacitor as shown in FIG. 9. A switch 45 is used for selecting one of reactive element 42A and reactive element42B. In other embodiments, switch 45 is omitted and only one of reactive element 42Aand reactive element42B is provided, effectively resulting in the configuration shown in FIGS. 3, 6, or 9. Furthermore, pre- distorter40 optionally comprises a buffer amplifier 44, shown as the source follower of FIG. 6.

Comparing FIGS. 3 and 11, and using the depicted setting of switch 45, non-linear dissipative element 41 corresponds to diode D1 and reactive element 42A to capacitor Cbp. As described above, when increasing power, the impedance of the non-linear dissipative element 41 increases, thereby causing more power to be routed through reactive element 42A. Consequently, the ratio between the power inputted into pre-distorter 10, 40 and the power that is dissipated in non-linear dissipative element D1, 41, increases, thereby causing an increase in gain of pre-distorter 10, 40.

Amplifier system 100D, or equally amplifier systems 100A-100C, may comprise a compound semiconductor die on which amplifier PA1 and at least part of analog pre- distorter 10, 20, 30, 40 are arranged. For example, referring to FIG. 11, power amplifier PA1 and non-linear dissipative element 41 can be arranged on the compound semiconductor die. Remaining components 42A, 42B, 43, 44, 45 may or may not be at least partially arranged on the compound semiconductor die. For example, if reactive element 42A is formed using a capacitor, this capacitor can be realized using a capacitor on the compound semiconductor die, such as metal-insulator-metal capacitor. Alternatively, if reactive element 42B is formed using an inductor, this inductor can be realized using one or more bond wires.

Parts of biasing unit 43 can be integrated on the compound semiconductor die. For example, referring to 6, some or all of capacitor C3, resistor R1, and inductors L1, L2, can be integrated on the compound semiconductor die. In addition, inductors L1, L2, acting as RF choke inductors, can each be formed using one or more bond wires.

Parts of buffer amplifier 44 can be integrated on the compound semiconductor die. For example, referring to 6, capacitor C4, acting as a capacitive RF short, can be integrated on the compound semiconductor die. RF choke inductor L3 that is connected in between electrical ground and a source of the source follower can be realized using one or more bond wires. DC block capacitor C5 can similarly be integrated on the compound semiconductor die. Capacitors C4, C5 may for example be realized using metal-insulator- metal capacitors.

The Applicant has found the analog pre-distorter has particular advantages when used in combination with compound semiconductor technologies, such as III-V semiconductor technologies or II-VI semiconductor technologies, when the operational frequency lies above 1 GHz, and when the amplifier is configured for outputting a power that exceeds 0.5W.

For example, the compound semiconductor die may comprise a Gallium Arsenide based semiconductor die or a Gallium Nitride based semiconductor die, and the amplifier may comprise a power field-effect transistor, wherein the non-linear dissipative element comprises a Schottky diode, and wherein the buffer amplifier comprises a source follower. However, the pre-distorter is equally applicable to other semiconductor technologies, such as Silicon based semiconductor technologies, operating at the same or lower operational frequencies.

In the embodiments described above, several different components have been described that can be realized in different or identical semiconductor technologies. For example, components of the pre-distorter can be manufactured using different semiconductor technologies. The semiconductor dies on which these components are integrated can be combined into a single package. Additionally, or alternatively, the pre- distorter and the amplifier can be arranged on the same semiconductor die or on different semiconductor dies. The pre-distorter and the amplifier can be individually packaged or the pre-distorter and amplifier are packaged in the same package.

For example, the amplifier may comprise a GaN field-effect transistor, a Si laterally diffused metal-oxide-semiconductor transistor, a GaAs heterojunction bipolar transistor, or a In(Ga)P heterojunction bipolar transistor. The non-linear dissipative element is preferably a diode that can be realized in these technologies, or a diode that is realized using a different semiconductor technology, such as Si MOS or Si CMOS technology. The other components, such as the capacitors and inductors, can in turn be realized in the same or different semiconductor technology as the non-linear dissipative element or in the same or different semiconductor technology as the amplifier.

The pre-distorter can be provided as a separate packaged component or can be packaged together with the power amplifier.

In the above, embodiments of the present disclosure have been described in detail. However, various modifications to these embodiments are possible without departing from the scope of the present disclosure, which is defined by the appended claims and their equivalents.

1. An amplifier system, comprising an amplifier having an input terminal and an output terminal, and an analog pre-distorter, wherein the analog pre-distorter comprises:
an input node for receiving an RF signal at an operational frequency ω;
an output node connected to the input terminal of the amplifier;
a buffer amplifier having a buffer input and a buffer output that is connected to the output node, wherein the buffer amplifier comprises a source follower or emitter follower;
a parallel connection of a non-linear dissipative element and a reactive element, wherein one end of the parallel connection is connected to the input node and wherein another end of the parallel connection is connected to the buffer input; and
a biasing unit for DC biasing the non-linear dissipative element;
wherein the non-linear dissipative element has a non-linear current-voltage relationship, wherein a dynamic resistance R_{dyn} of the non-linear dissipative element
decreases with increasing DC current through the non-linear dissipative element such that for a given DC bias current through the non-linear dissipative element, a power gain of the analog pre-distorter expands when power of the RF signal is increased;
wherein the amplifier displays gain compression and a phase shift between the input terminal and output terminal that decreases or increases with increasing power of the RF signal;
wherein the analog pre-distorter is configured for at least partially compensating the gain compression and/or decrease or increase in phase shift of the amplifier;
wherein the operational frequency lies above 1 GHz, and wherein the amplifier is configured for outputting a power that exceeds 0.5W; and
wherein the amplifier and at least part of the analog pre-distorter are integrated on a compound semiconductor die.

2. The amplifier system according to claim 1, wherein the non-linear element is configured such that a ratio between a voltage swing of a voltage over the non-linear
dissipative element and a current swing of a current through the non-linear dissipative element for said given DC bias current through the non-linear dissipative element increases when said voltage swing increases.

3. The amplifier system according to claim 1, wherein the non-linear current- voltage relationship describes a relationship between a value of the current through the non-linear dissipative element at a given time instant and a value of the voltage over the non-linear dissipative element at said given time instant, wherein a DC current-voltage relationship of the non-linear dissipative element at least substantially equals said non- linear current-voltage relationship.

4. The amplifier system according to claim 1, wherein the biasing unit is configured to control the biasing of the non-linear dissipative element such that the
dynamic resistance R_{dyn} of the non-linear dissipative element relates to a magnitude of the impedance Z of the reactive element at the operational frequency according to:
0.05R_{dyn} < IZI < 5R_{dyn}

5. The amplifier system according to claim 4, wherein the impedance Z of the reactive element at the operational frequency is further configured such that:
a phase delay imparted to the RF signal by the analog pre-distorter increases when power of the RF signal is increased, wherein the reactive element comprises a capacitor; or
a phase delay imparted to the RF signal by the analog pre-distorter decreases when power of the RF signal is increased, wherein the reactive element comprises an inductor, wherein the parallel connection comprises a DC block capacitor arranged in series with the reactive element.

6. The amplifier system according to claim 1, wherein the non-linear
dissipative element comprises a diode, wherein the biasing unit is configured to bias the diode above turn-on.

7. The amplifier system according to claim 1, wherein the compound semiconductor die comprises a Gallium Arsenide based semiconductor die or a Gallium
Nitride based semiconductor die, wherein the amplifier comprises a power field-effect transistor, wherein the non-linear dissipative element comprises a Schottky diode, and wherein the buffer amplifier comprises a source follower.

8. The amplifier system according to claim 1, further comprising a DC block capacitor arranged between the input node and said one end of the parallel connection,
wherein said one end of the parallel connection is connected to the biasing unit through a first RF choke inductor, and wherein said other end of the parallel connection is electrically grounded through a second RF choke inductor, wherein the first and second RF choke inductors are formed using one or more bond wires.

9. The amplifier system according to claim 1, further comprising a power supply connected to a drain of the source follower or to a collector of the emitter follower, the amplifier system further comprising a capacitive RF short connected to the drain of the source follower or to the collector of the emitter follower, and a RF choke inductor connected in between electrical ground and a source of the source follower or an emitter of the emitter follower, the amplifier system further comprising a DC block capacitor in between the source of the source follower or the emitter of the emitter follower and the input terminal of the amplifier, wherein the RF choke inductor is formed using one or more bond wires.

10. The amplifier system according to claim 1, wherein the parallel connection comprises a further reactive element, the amplifier system further comprising a switch for
selecting one among the reactive element and the further reactive element to be electrically connected between said one end of the parallel connection and said another end of the parallel connection.

11. An amplifier system, comprising an amplifier having an input terminal and an output terminal, and an analog pre-distorter, wherein the analog pre-distorter comprises:
an input node for receiving an RF signal at an operational frequency ω;
an output node connected to the input terminal of the amplifier;
a buffer amplifier having a buffer input and a buffer output that is connected to the output node, wherein the buffer amplifier comprises a source follower or emitter follower;
a parallel connection of a non-linear dissipative element and a reactive element, wherein one end of the parallel connection is connected to the input node and wherein another end of the parallel connection is connected to the buffer input; and
a biasing unit for DC biasing the non-linear dissipative element;
wherein the non-linear dissipative element has a non-linear current-voltage relationship, wherein a dynamic resistance R_{dyn} of the non-linear dissipative element increases with increasing DC bias voltage across the non-linear dissipative element such that for a given DC bias voltage across the non-linear dissipative element, a power gain of the analog pre-distorter expands when power of the RF signal is increased;
wherein the amplifier displays gain compression and a phase shift between the input terminal and output terminal that decreases or increases with increasing power of the RF signal;
wherein the analog pre-distorter is configured for at least partially compensating the gain compression and/or decrease or increase in phase shift of the amplifier;
wherein the operational frequency lies above 1 GHz, and wherein the amplifier is configured for outputting a power that exceeds 0.5W; and
wherein the amplifier and at least part of the analog pre-distorter are integrated on a compound semiconductor die.

12. The amplifier system according to claim 11, wherein the non-linear element is configured such that a ratio between a voltage swing of a voltage of the RF signal over the non-linear dissipative element and a current swing of a current of the RF signal through the non-linear dissipative element for said given DC bias voltage over the non-linear dissipative element increases when said voltage swing increases.

13. The amplifier system according to claim 11, wherein the non-linear current- voltage relationship describes a relationship between a value of the current through the non-linear dissipative element at a given time instant and a value of the voltage over the non-linear dissipative element at said given time instant, wherein a DC current-voltage relationship of the non-linear dissipative element at least substantially equals said non- linear current-voltage relationship.

14. The amplifier system according to claim 11, wherein the biasing unit is configured to control the biasing of the non-linear dissipative element such that the dynamic resistance R_{dyn} of the non-linear dissipative element relates to a magnitude of the impedance Z of the reactive element at the operational frequency according to:
0.05R_{dyn} < IZI < 5R_{dyn}

15. The amplifier system according to claim 14, wherein the impedance Z of the reactive element at the operational frequency is further configured such that:
a phase delay imparted to the RF signal by the analog pre-distorter increases when power of the RF signal is increased, wherein the reactive element comprises a capacitor; or
a phase delay imparted to the RF signal by the analog pre-distorter decreases when power of the RF signal is increased, wherein the reactive element comprises an inductor, wherein the parallel connection comprises a DC block capacitor arranged in series with the reactive element.

16. The amplifier system according to claim 11, wherein the non-linear dissipative element comprises a diode, wherein the biasing unit is configured to bias the diode above turn-on.

17. The amplifier system according to claim 11, wherein the compound semiconductor die comprises a Gallium Arsenide based semiconductor die or a Gallium Nitride based semiconductor die, wherein the amplifier comprises a power field-effect transistor, wherein the non-linear dissipative element comprises a Schottky diode, and wherein the buffer amplifier comprises a source follower.

18. The amplifier system according to claim 11, further comprising a DC block capacitor arranged between the input node and said one end of the parallel connection,
wherein said one end of the parallel connection is connected to the biasing unit through a first RF choke inductor, and wherein said other end of the parallel connection is electrically grounded through a second RF choke inductor, wherein the first and second RF choke inductors are formed using one or more bond wires.

19. The amplifier system according to claim 11, further comprising a power supply connected to a drain of the source follower or to a collector of the emitter follower, the amplifier system further comprising a capacitive RF short connected to the drain of the source follower or to the collector of the emitter follower, and a RF choke inductor connected in between electrical ground and a source of the source follower or an emitter of the emitter follower, the amplifier system further comprising a DC block capacitor in between the source of the source follower or the emitter of the emitter follower and the input terminal of the amplifier, wherein the RF choke inductor is formed using one or more bond wires.

20. The amplifier system according to claim 11, wherein the parallel connection comprises a further reactive element, the amplifier system further comprising a switch for selecting one among the reactive element and the further reactive element to be electrically connected between said one end of the parallel connection and said another end of the parallel connection.
